(19) United States
(12) Patent Application Publication
(10) Pub. No.: US 2004/0105023 A1
(43) Pub. Date: Jun. 3, 2004

(54) Solid state imaging device with an output section having reduced power consumption, and manufacturing method thereof

(75) Inventor: Yoshihiro Okada, Hashima-shi (JP)

Correspondence Address: HOGAN & HARTSON L.L.P., 500 S. GRAND AVENUE, SUITE 1900, LOS ANGELES, CA, 90071-2611, US

(73) Assignee: SANYO ELECTRIC CO., LTD

(21) Appl. No.: 10/713,487

(22) Filed: Nov. 14, 2003

(30) Foreign Application Priority Data
Nov. 14, 2002 (JP) 2002-330673

(51) Int. Cl. H04N 5/335

(52) U.S. Cl. 348/311; 348/294

(57) ABSTRACT

A solid state imaging device comprises a plurality of first channel regions of one conductive type arranged in parallel on a surface of a semiconductor substrate of a reverse conductive type. The imaging device further comprises a drain region formed in a space between the plurality of first channel regions, and a plurality of first transfer electrodes formed over the plurality of first channel regions. The plurality of first transfer electrodes are arranged in parallel to one another along a direction intersecting the first channel regions. The imaging device further includes a second channel region of the one conductive type formed on the main surface of the semiconductor substrate as a connected portion of the first channel regions. The second channel region extends along a direction intersecting the first channel regions. The imaging device further comprises a plurality of second transfer electrodes formed over the second channel region and arranged in parallel to one another along a direction intersecting the second channel region. The second channel region has an impurity concentration lower than that of the first channel regions.

### BACKGROUND OF THE INVENTION

1. Field of the Invention

The present invention relates to a CCD solid state imaging device and its manufacturing method, and more particularly to reduction of power consumption in an output section of such an element.

2. Description of the Related Art

FIG. 6 is a schematic structural diagram of a frame transfer type CCD solid state imaging device. This frame transfer type CCD solid state imaging device comprises an imaging section i, a storage section s, a horizontal transfer section h, and an output section d. Information charges generated in the imaging section i are transferred to the storage section s at a high speed. The information charges are then retained in the storage section s, transferred in units of one line to the horizontal transfer section h, and subsequently transferred from the horizontal transfer section h to the output section d in units of one pixel. The output section d converts an amount of charges for one pixel into a voltage value. Changes in the voltage values obtained as such are employed as the CCD output.

When excessive information charges are generated in the imaging section i, a phenomenon referred to as blooming, in which information charges overflow into surrounding pixels, occurs. In order to prevent blooming, an overflow drain structure for discharging unnecessary information charges is provided. An overflow drain structure may be of a vertical overflow drain type or a horizontal overflow drain type.

In a vertical overflow drain structure, an NPN structure is formed on the front surface of an N-type semiconductor substrate, a P well which is a P-type diffusion layer in the substrate depth direction, and an N well which is an N-type diffusion layer. By applying a positive voltage to the rear surface of the substrate to deplete the P well, excessive charges in a photodiode formed on the front surface can clear the potential barrier created by the P well and be discharged to the substrate.

In a horizontal overflow drain structure, a drain region composed of an N⁺ diffusion layer is provided adjacent to a light-receiving pixel. When using this arrangement, it is unnecessary to form an NPN structure in the substrate depth direction. An N well for forming components such as a light-receiving pixel and a CCD register is formed on a surface of a P-type semiconductor substrate.

The impurity concentration of the N well is determined based on the handling charge amount (storable charge amount) in each pixel in the imaging section i and the storage section s. Because of demands for size reduction and increased number of pixels in CCD solid state imaging devices, attempts to increasing the size of the pixels constituting the imaging section i and the storage section s in order to ensure the required handling charge amount is both disadvantageous and impractical. Therefore, the handling charge amount is commonly attained by increasing the dopant concentration of the N well. Conventionally, the dopant concentration of the N well is determined in this manner by using as a reference the handling charge amount in the imaging section i and the storage section s, and an N well uniformly having the determined dopant concentration is formed in the entire region including the imaging section i, the storage section s, the horizontal transfer section h; and the output section d.

FIGS. 7 and 8 show cross-sectional views of the essential portions of a CCD solid state imaging device having a conventional horizontal overflow drain structure. FIG. 7 shows a cross-sectional view taken along the charge transfer direction of a vertical shift register. Specifically, FIG. 7 illustrates a cross-section around the output end of the storage section s serving as a vertical shift register. The illustrated view further includes a cross-section of the horizontal transfer section h connected to the output end of the storage section s. FIG. 8 shows a cross-sectional view taken along the charge transfer direction of the horizontal shift register. Specifically, FIG. 8 illustrates a cross-section around the output end of the horizontal shift register, including a floating diffusion and a reset transistor constituting a part of the output section.

The N well 4 is formed by performing ion implantation and diffusion treatment of N-type dopants in a surface of a P-type silicon substrate 2. The P-type layer (P_{sub}) 6 located under the N well 4 is provided in the original silicon substrate 2 itself.

In FIG. 7, information charges are transferred to the right (using the drawing as a reference) sequentially in the potential wells of a vertical shift register formed in the N well 4, and subsequently transferred out into a potential well formed under an electrode 14-1 of the horizontal shift register. In FIG. 8, information charges are transferred to the left (using the drawing as a reference) sequentially in the potential wells of the horizontal shift register formed in the N well 4 by transfer clocks φ_{H1}, φ_{H2} applied to the transfer electrodes 14-1,14-2. The information charges are transferred to the floating diffusion (FD) 18 via a channel under the output gate (OG) 16.

The floating diffusion 18 is an N⁺ diffusion layer. When the adjacent reset gate (RG) 22 is turned on, the potential in the floating diffusion 18 is set to the potential V_{RD} of the reset drain (RD) 20. When information charges are transferred from the horizontal shift register to the floating diffusion 18, the potential of the floating diffusion 18 is changed in accordance with the transferred charge amount. This potential change is detected and amplified by an output amplifier 30. The output voltage V_{OUT} from the output amplifier 30 serves as the CCD output. The output amplifier 30 is a source follower circuit configured with MOS type drive transistors 32 and MOS type load transistors 34, and driven using a power source voltage V_{DD} (which may be 5V, for example). For the purpose of simplifying the CCD drive circuit by a shared use of a power source circuit, the power source voltage V_{DD} may be simultaneously used as the reset drain voltage V_{RD}. In that case, the reset potential of the floating diffusion 18 is identical with the power source voltage V_{DD}.

In recent years, many small and lightweight devices having CCD solid state imaging devices, such as digital cameras and cell phones with photographing function, have been developed. In a small and lightweight device, reduced power consumption is desired because the size of the battery must also be reduced. In general, lowering of a drive voltage is effective in achieving reduced power consumption. In a CCD solid state imaging device, the power consumption may be reduced by lowering the reset drain voltage V_{RD} and the power source voltage V_{DD}, for example. A relatively large current is particularly required to drive the output amplifier, resulting in high power consumption in this section. Accordingly, lowering of the voltage for driving the output amplifier would be effective in reducing power consumption.

However, lowering of the reset drain voltage V_{RD} and the power source voltage V_{DD} causes undesirable degradation in the efficiency of information charge transfer from the horizontal shift register to the floating diffusion 18. More specifically, when the reset drain voltage V_{RD} and the power source voltage V_{DD} are lowered, the potential of the reset drain 20 becomes shallow, which in turn sets a shallow potential in the floating diffusion 18. Consequently, the difference between the potential under the output gate 16 and the potential of the floating diffusion 18 is reduced, disadvantageously decreasing the charge storage capacity of the floating diffusion 18. As a result, information charges transferred from the horizontal shift register cannot be sufficiently received in the floating diffusion 18, causing degradation in the efficiency of information charge transfer.

Although lowering the voltage of the transfer clock of the horizontal shift register so as to provide a shallower potential in the horizontal shift register region may appear to be an additional solution, the voltage of the transfer clock of the horizontal shift register has already been minimized in recent designs. Furthermore, due to pinning phenomenon, there exists a lower allowable limit to a channel potential of an embedded channel type CCD. Accordingly, the range within which the potential of the transfer clock can be lowered to provide a shallower potential in the channel region is restricted.

### SUMMARY OF THE INVENTION

According to one aspect of the present invention, a solid state imaging device comprises a plurality of first channel regions of one conductive type arranged on a main surface of a semiconductor substrate of a reverse conductive type. The plurality of first channel regions are arranged in parallel to one another and spaced apart at predetermined distances. The imaging device further comprises a drain region formed in a space between the plurality of first channel regions, and a plurality of first transfer electrodes formed in the plurality of first channel regions. The plurality of first transfer electrodes are arranged in parallel to one another along a direction intersecting the first channel regions. The imaging device further includes a second channel region of the one conductive type formed on the main surface of the semiconductor substrate as a connected portion of the first channel regions. The second channel region extends along a direction intersecting the first channel regions. The imaging device further comprises a plurality of second transfer electrodes formed in the second channel region and arranged in parallel to one another along a direction intersecting the second channel region. The second channel region has an impurity concentration lower than that of the first channel regions.

Another aspect of the present invention provides a method for manufacturing a solid state imaging device including an imaging section having a plurality of light-receiving pixels arranged in a matrix, a vertical transfer section having a plurality of vertical shift registers arranged corresponding to respective columns of the plurality of light-receiving pixels, a horizontal transfer section formed on an output side of the plurality of vertical shift registers, and an output section formed on an output side of the horizontal transfer section. The manufacturing method comprises a first step of forming a channel region by doping dopants of a reverse conductive type to a main surface of a semiconductor substrate of one conductive type, a second step of forming a resist pattern covering a region corresponding to the horizontal transfer section and the output section on the main surface of the semiconductor substrate, and a third step of doping dopants of the reverse conductive type to the main surface of the semiconductor substrate using the resist pattern as a mask. A channel region of the horizontal transfer section and the output section is formed to have an dopant concentration lower than that of a channel region of the imaging section and the vertical transfer section.

### BRIEF DESCRIPTION OF THE DRAWINGS

FIG. 1 shows a schematic plan view of a connecting portion between vertical shift registers and a horizontal shift register in a CCD solid state imaging device according to an embodiment of the present invention.

FIG. 2A shows a schematic cross-sectional view of a vertical CCD register provided with a horizontal type overflow drain, taken along a direction intersecting the charge transfer direction. FIG. 2B is a diagram illustrating a potential distribution in a region corresponding to the cross-section of FIG. 2A.

FIG. 3 shows a schematic cross-sectional view taken along a transfer channel of a vertical shift register in a CCD solid state imaging device according to the embodiment of the present invention.

FIG. 4 shows a schematic cross-sectional view taken along a transfer channel of a horizontal shift register in a CCD solid state imaging device according to the embodiment of the present invention.

FIGS. 5A and 5B are schematic element top views for explaining the process for forming the N well in a CCD solid state imaging device according to the embodiment of the present invention.

FIG. 6 is a schematic structural diagram of a frame transfer type CCD solid state imaging device.

FIG. 7 shows a schematic cross-sectional view taken along a channel of a vertical shift register in a CCD solid state imaging device according to a related art.

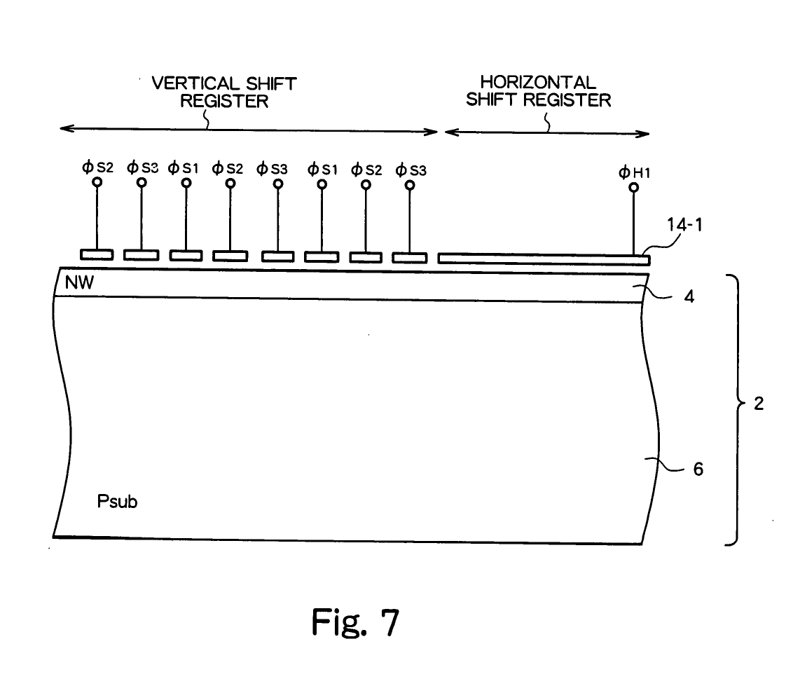

FIG. 8 shows a schematic cross-sectional view taken along a channel of a horizontal shift register in a CCD solid state imaging device according to a related art.

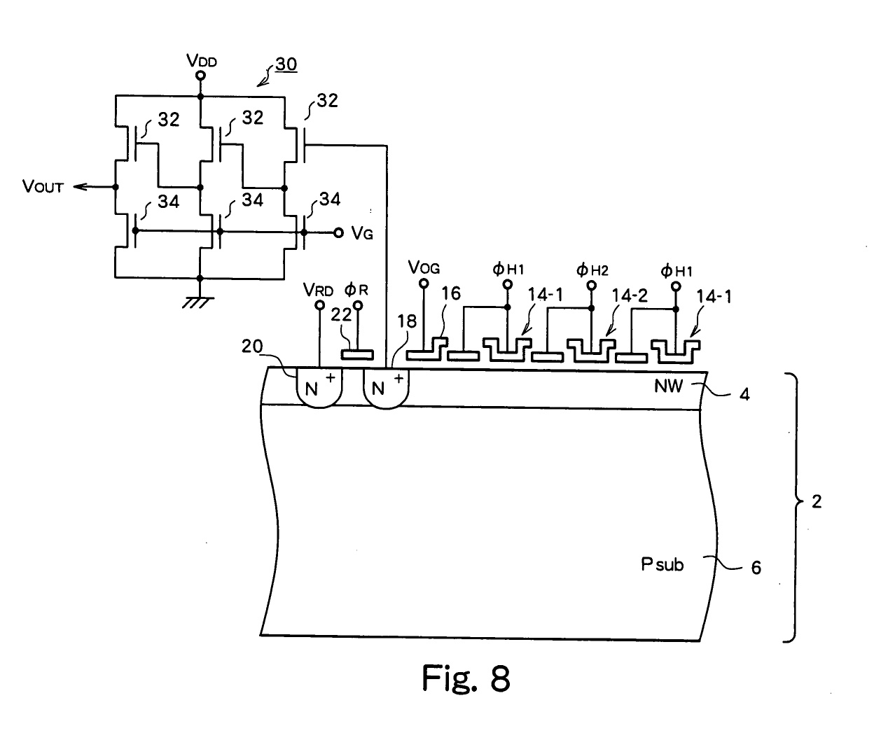

### DESCRIPTION OF THE PREFERRED EMBODIMENT

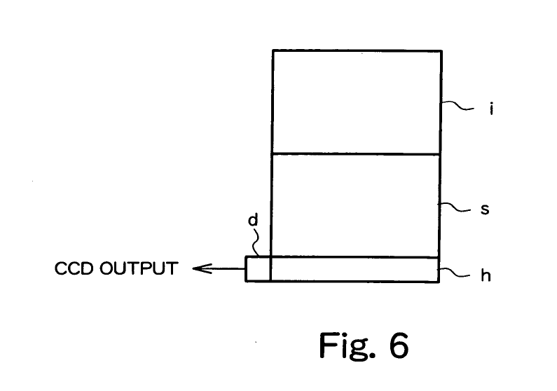

A preferred embodiment of the present invention is next described referring to the drawings. The example used to illustrate the preferred embodiment describes an example of application of the present invention in a frame transfer type CCD solid state imaging device. A schematic structure of a frame transfer type CCD solid state imaging device is as shown in FIG. 6 and described above. A frame transfer type CCD solid state imaging device comprises an imaging section i, a storage section s, a horizontal transfer section h, and an output section d. The imaging section i extends in a vertical direction and comprises a plurality of vertical shift registers arranged in parallel to one another. Each bit of each vertical shift register serves as a photodiode constituting a light-receiving pixel. The storage section s comprises a plurality of light-shielded vertical shift registers formed as connected portions of the vertical shift registers in the imaging section i. Each bit of each vertical shift register in the storage section s serves as a photodiode constituting a storage pixel. The horizontal transfer section h comprises a single horizontal shift register extending in the horizontal direction. Each bit of the horizontal shift register is connected to receive output from a corresponding vertical shift register of the storage section s. The output section d includes a capacitor for temporarily retaining charges transferred and output from the horizontal transfer section h, and a reset drain for discharging the charges retained in the capacitor. With the above arrangement, information charges stored in the light-receiving pixels of the imaging section i are transferred separately for each pixel to the storage pixels of the storage section s. Thereafter, the information charges are transferred in units of one line to the horizontal transfer section h, and subsequently transferred from the horizontal transfer section h to the output section d in units of one pixel. The output section d converts an amount of charges for one pixel into a voltage value. Changes in the voltage values obtained as such are supplied to an external circuit as the CCD output.

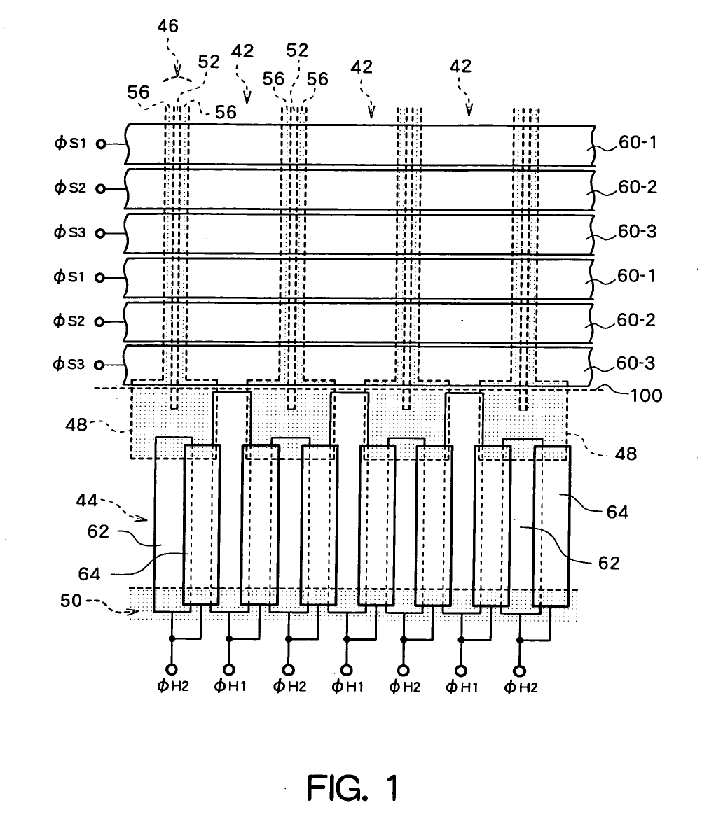

FIG. 1 is a diagram for explaining the essential portions of a CCD solid state imaging device, showing a schematic cross-sectional view of a connecting portion between the vertical shift registers and the horizontal shift register. The structure shown in FIG. 1 is made by first forming an N well by doping a surface of a P-type semiconductor substrate with N-type dopants, and further performing other multiple procedures.

More specifically, an oxide film is formed and a polysilicon layer is laminated on a substrate having an N well formed on its surface. The polysilicon layer is patterned into a plurality of transfer electrodes 60, 62, 64. Subsequently, a resist pattern is formed in accordance with the arrangement of the transfer electrodes. Using this resist pattern as a mask, the N well is doped with P-type dopants to form isolation regions 46, 48, 50. Each of these isolation regions 46, 48, 50 electrically isolates two N well regions contacting their boundaries with the isolation region, thereby defining channel regions 42, 44 which serve as the charge transfer paths on the semiconductor main surface. The transfer electrodes and the channel regions created in this manner define the light-receiving pixels, the vertical shift registers, and the horizontal shift register.

When employing a horizontal overflow drain structure, an overflow drain region 52 is provided within the isolation region 46 in an elongated shape in parallel to the channel region 42. The overflow drain region 52 is formed by performing ion implantation of N-type dopants at a high concentration in a central portion with respect to the width direction of the isolation region 46. The overflow drain region 52 introduces a potential barrier with respect to adjacent isolation regions.

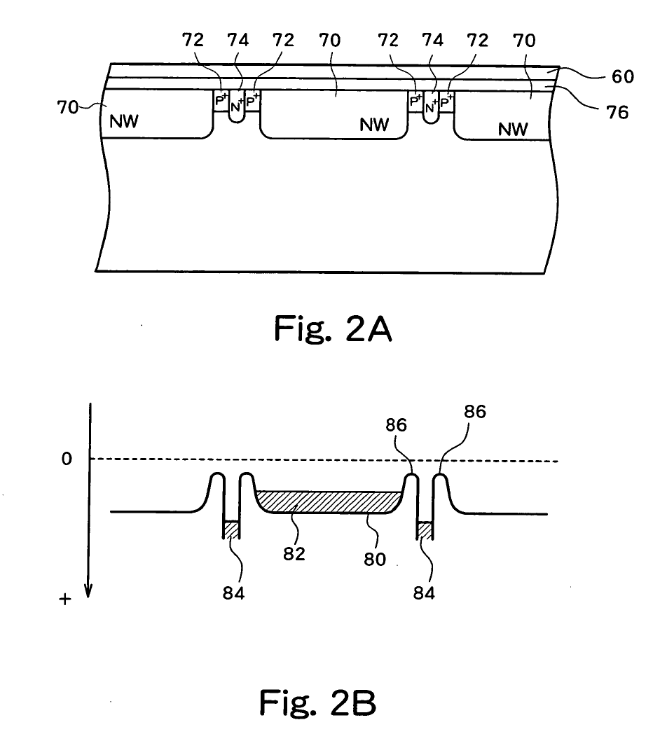

Referring to FIG. 2A, the N well 70, P⁺ diffusion layer 72, and N⁺ diffusion layer 74 are formed in a surface of a P-type semiconductor substrate P_{sub}, corresponding to the channel region 42, isolation region 56, and drain region 52, respectively. Further, a transfer electrode 60 is arranged on the substrate surface with a gate oxide film 76 interposed therebetween. Referring to the potential distribution diagram of FIG. 2B, the potential is given on the vertical axis with a positive potential value increasing in the downward direction. The N well 70 is depleted by a voltage applied to the transfer electrode 60 and a potential well 80 is formed in the N well 70. Information charges 82 can be stored in this potential well 80. The N⁺ diffusion layer 74 constitutes the drain 84. The P⁺ diffusion layer 72 serving as the isolation region 56 provides a potential barrier 86 between the potential well 80 in a transfer channel and the drain 84. When excessive information charges are generated in or flow into the potential well 80, the excess portion of the charges clear the potential barrier 86 to be discharged into the drain 84. This prevents generation of blooming in which excessive charges overflow into surrounding pixels.

Again referring to FIG. 1, a plurality of transfer electrodes 60 of the vertical shift registers and a plurality of transfer electrodes 62, 64 of the horizontal shift register are arranged, respectively, in juxtaposition along the charge transfer direction. In the present embodiment, the vertical CCD registers are operated in a 3-phase drive. More specifically, transfer clocks φ_{S1}, φ_{S2}, φ_{S3} are applied to the periodically arranged transfer electrodes 60-1, 60-2, 60-3, respectively, to transfer information charges in a downward direction in FIG. 1.

In the horizontal shift register, the transfer electrodes 62 are composed of a first layer of polysilicon, while the transfer electrodes 64 are formed with a second layer of polysilicon. The horizontal shift register is operated in a 2-phase drive by applying transfer clock φ_{H1} or φ_{H2} to each pair of adjacent transfer electrodes 62 and 64. A stepwise potential distribution is formed under the transfer electrodes 62 and 64 in accordance with the level difference between the transfer electrodes 62 and 64, such that information charges are stored in the channel region under the transfer electrodes 62. Because driving a transfer electrode 62 together with a transfer electrode 64 juxtaposed on the right side (in FIG. 1) of the transfer electrode 62 by the same transfer clock, information charges are transferred within the horizontal shift register in a leftward direction in FIG. 1.

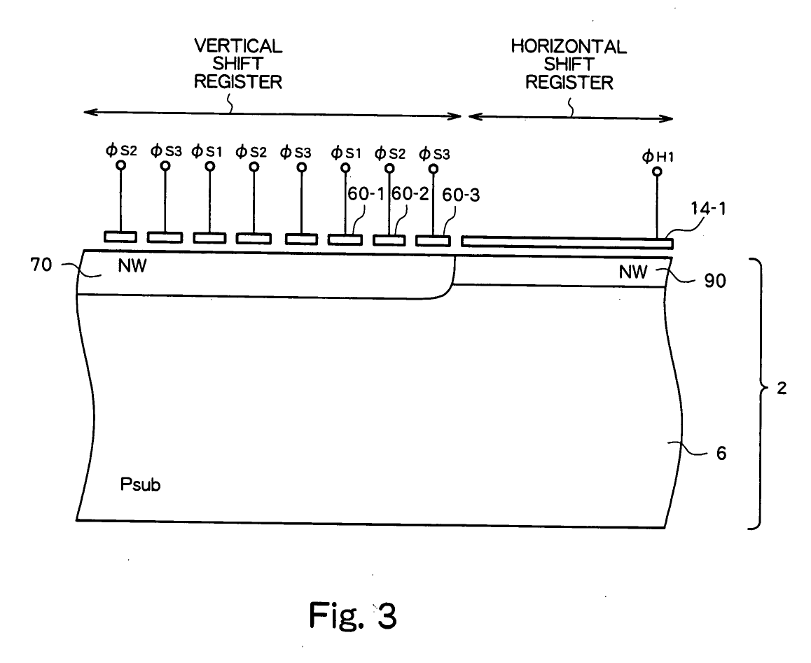

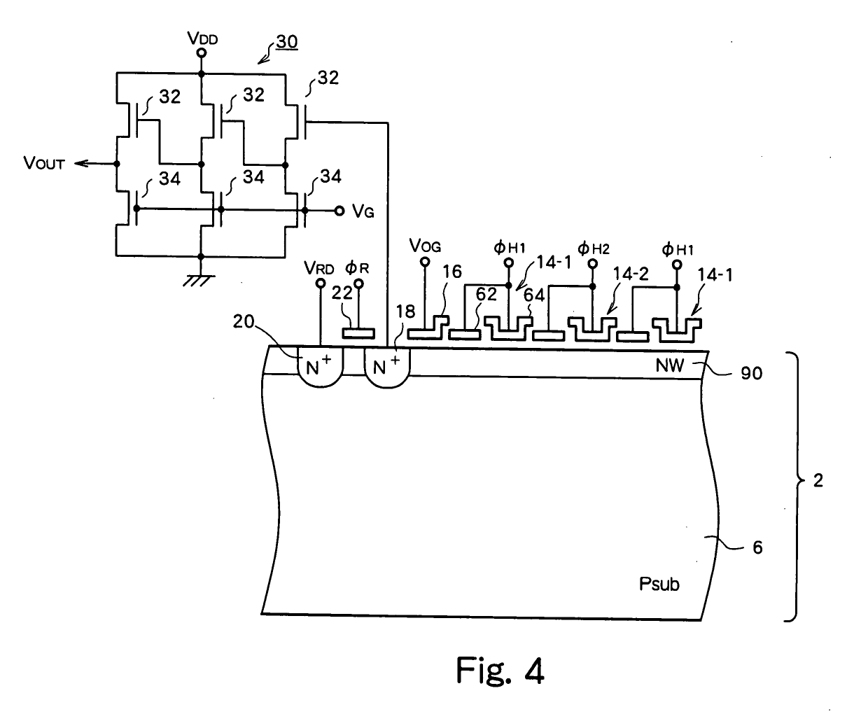

FIG. 3 shows a schematic cross-sectional view taken along the transfer direction of a vertical shift register. Specifically, FIG. 3 illustrates a cross-section around the output end of a storage section s serving as the vertical shift registers. The illustrated view further includes a cross-section of the horizontal transfer section h connected to the output end of the storage section s. FIG. 4 shows a cross-sectional view taken along the charge transfer direction of the horizontal shift register. Specifically, FIG. 4 illustrates a cross-section around the output end of the horizontal shift register, including a floating diffusion 18 and a reset drain 20 constituting a part of the output section.

As described above, ion implantation and diffusion are performed in a P-type silicon substrate 2 using N-type dopants to form an N well in the surface region of the substrate 2. In the present embodiment, the ion implantation using N-type dopants for forming the N well is conducted in two separate processes while changing the areas to be processed. As a result, two types of N wells 70 and 90 having different dopant concentrations are created. The N well 70 having a relatively high dopant concentration is formed into the imaging section i and the storage section s. The N well 90 having a relatively low dopant concentration is formed into the horizontal transfer section h and the output section d. FIG. 3 shows both of the N wells 70 and 90, while FIG. 4 shows the N well 90. The dopant concentration of the N well 70 is determined from the aspect of ensuring a sufficient handling charge amount in the imaging section i and the storage sections. In contrast, the dopant concentration of the N well 90 is determined taking into account the reduction of the voltage for driving the output section d, as described below.

The transfer electrodes are arranged on the substrate surface with an oxide film 76 (not shown in FIGS. 3 and 4) interposed therebetween. The vertical shift registers of the storage section s include electrode groups 60-1,60-2,60-3 driven by the 3-phase transfer clocks φ_{S1}, φ_{S2}, φ_{S3}. The horizontal shift register includes electrode groups 14-1, 14-2 driven by the 2-phase transfer clocks φ_{H1}, φ_{H2}. By applying a positive voltage sequentially to the individual electrode groups, potential wells formed in the N well located under the electrodes are shifted, thereby also shifting the information charges stored in the potential wells. For example, in FIG. 3, a charge packet is sequentially transferred in a rightward direction through the vertical shift register, and subsequently read out in a potential well formed under the electrode 14-1 of the horizontal shift register. In FIG. 4, information charges are transferred in a leftward direction through the horizontal shift register, and further transferred to the floating diffusion (FD) 18 via the channel under the output gate (OG) 16 to which is applied a direct current.

The floating diffusion 18 is an N⁺ diffusion layer which forms a capacitor for storing information charges transferred and output from the horizontal shift register. The floating diffusion 18, reset drain (RD) 20, and reset gate (RG) 22 constitute a reset transistor. The reset drain 20 is composed of an N⁺ diffusion layer. The reset drain 20 is maintained at a constant reset drain potential V_{RD}. In the present embodiment, the power source voltage V_{DD} is used as the reset drain potential V_{RD}. When the reset gate 22 is turned on by a reset clock φ_{R} applied to the reset gate 22, a channel is formed under the reset gate 22. Accordingly, information charges stored in the floating diffusion 18 are transferred and discharged into the reset drain 20. When the reset gate 22 is in an OFF state, the floating diffusion 18 and the PN junction with the P_{sub} contacting the floating diffusion 18 are in electrically floating state. When information charges are shifted from the horizontal shift register into the floating diffusion 18 in this state, the information charges are temporarily stored in the PN junction capacitor, and the potential of the floating diffusion 18 is changed in accordance with the stored charge amount. This potential change is detected and amplified by the output amplifier 30. The output voltage V_{OUT} from the output amplifier 30 serves as the CCD output.

The output amplifier 30 may be configured as a 3-stage source follower circuit using a MOS transistor formed on the substrate 2. In the output amplifier 30, drains and sources of the drive transistor 32 and the load transistor 34 are composed of the N⁺ diffusion layer formed on the substrate 2. A channel formed between the drain and the source is controlled using a gate electrode composed of a polysilicon electrode layer formed over a gate oxide film. In the output section d of the present embodiment, the power source voltage V_{DD} applied to the reset drain 20 and the drain diffusion layer of the drive transistor 32 in the output amplifier 30 is lowered (to 2.9V, for example) below that of a conventional power source voltage, thereby reducing power consumption.

The dopant concentration of the N well 90 is determined such that the potential under the transfer electrodes 62 in an OFF state becomes shallower than the potential of the floating diffusion 18, so as to generate a sufficient fringe electric field from the last transfer electrode toward the floating diffusion 18, thereby ensuring a favorable transfer efficiency. It should be noted that the transfer channel width of the horizontal shift register can be increased relatively easily. Accordingly, even if the channel potential is made shallower, a sufficient handling charge amount can be treated by enlarging the surface area of the region under the transfer electrodes 62.

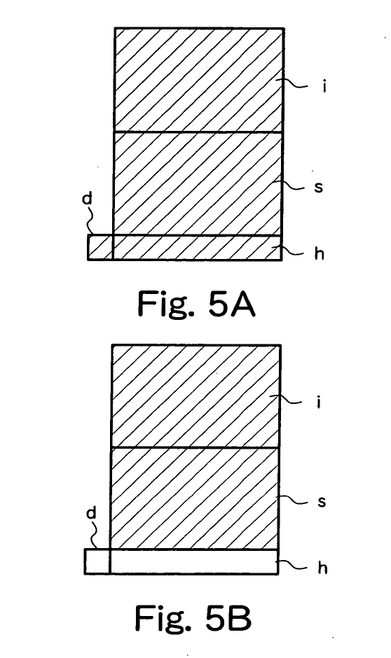

FIGS. 5A and 5B are schematic element top views for explaining the process for forming the N well in a CCD solid state imaging device according to the present embodiment. Ion implantation is performed using N-type dopants in the element forming region of the surface of the P-type silicon substrate 2. By performing this first step of introducing N-type dopants, a first N-type diffusion layer having a first dopant profile in the depth direction is formed in the region (marked with slanted lines in FIG. 5A) in which the imaging section i, storage section s, horizontal transfer section h, and the output section d are subsequently formed.

Subsequently, on the substrate 2 surface, a resist pattern is formed with an opening in the region (marked with slanted lines in FIG. 5B) in which the imaging section i and the storage section s are to be prospectively formed. The resist pattern is used as a mask to perform the second ion implantation step using N-type dopants. A heat diffusion treatment is also executed. By performing this second step of introducing N-type dopants, a second N-type diffusion layer having a second dopant profile compounded with the previously-formed first dopant profile is formed under the region in which the imaging section i and the storage section s are to be formed. In the above-described processing, the masks for the ion implantation, the heat diffusion, and the like are designed such that, in the final state, the boundary between the N well 70 and the N well 90 (between the storage section s and the horizontal transfer section h) matches the boundary between the last-row transfer electrode 60-3 of the vertical shift registers and the transfer electrodes 62 of the horizontal shift register which read out information charges from the vertical transfer channels. In FIG. 1, dotted line 100 indicates the boundary between the N well 70 and the N well 90. For example, the mask for the second ion implantation step may be formed to cover up to 1-2 μm above the dotted line 100 in FIG. 1. The high concentration N well doped and created using this mask is subsequently enlarged in planar directions during the heat diffusion process, so as to extend to the dotted line 100 after the final heat diffusion process.

After the above-described processing, the transfer electrodes 60,62,64 are provided on the semiconductor substrate surface. Subsequently, the isolation regions 46,48,50 and drain region 52 are formed in the semiconductor substrate surface to thereby complete the CCD solid state imaging device.

According to the above manufacturing method, the isolation regions are formed after the plurality of transfer electrodes are formed, thereby facilitating positional alignment between the transfer electrodes and isolation regions. More specifically, the channel regions are defined by performing ion implantation in accordance with the arrangement of the transfer electrodes. Compared to a case in which the transfer electrodes are created in accordance with the arrangement of the channel regions and the isolation regions, positional alignment between the transfer electrodes and the channel regions is facilitated according to the present method.

In the CCD solid state imaging device manufactured as described above, the drive voltage of the output section can be lowered to reduce power consumption without degrading the efficiency of information charge transfer from the horizontal transfer section to the output section.

What is claimed is:

1. A solid state imaging device, comprising:
a plurality of first channel regions of one conductive type arranged on a main surface of a semiconductor substrate of a reverse conductive type, the plurality of first channel regions being arranged in parallel to one another while being spaced apart at a predetermined distance;
a drain region formed in a space between the plurality of first channel regions;
a plurality of first transfer electrodes formed over the plurality of first channel regions and arranged in parallel to one another along a direction intersecting the first channel regions;
a second channel region of the one conductive type formed on the main surface of the semiconductor substrate of a reverse conductive type as a connected portion of the first channel regions, the second channel region extending along a direction intersecting the first channel regions; and
a plurality of second transfer electrodes formed over the second channel region and arranged in parallel to one another along a direction intersecting the second channel region; wherein
the second channel region has an impurity concentration lower than that of the first channel regions.

2. A solid state imaging device as defined in claim 1, wherein a boundary between the first channel region and the second channel region is set in accordance with a boundary between the last row of the plurality of first transfer electrodes and the second transfer electrodes.

3. A method for manufacturing a solid state imaging device including an imaging section having a plurality of light-receiving pixels arranged in a matrix, a vertical transfer section having a plurality of vertical shift registers arranged corresponding to respective columns of the plurality of light-receiving pixels, a horizontal transfer section formed on an output side of the plurality of vertical shift registers, and an output section formed on an output side of the horizontal transfer section, the manufacturing method comprising:
a first step of forming a channel region by doping dopants of a reverse conductive type to a main surface of a semiconductor substrate of one conductive type;
a second step of forming a resist pattern covering a region corresponding to the horizontal transfer section and the output section on the main surface of the semiconductor substrate; and
a third step of doping dopants of the reverse conductive type to the main surface of the semiconductor substrate using the resist pattern as a mask; wherein
a channel region of the horizontal transfer section and the output section is formed to have an dopant concentration lower than that of a channel region of the imaging section and the vertical transfer section.

4. A method for manufacturing a solid state imaging device as defined in claim 3, further comprising:
a fourth step of performing, after the second step, a step of forming a plurality of transfer electrodes on the main surface of the semiconductor substrate; and
doping dopants of the one conductive type to the semiconductor substrate through the plurality of transfer electrodes, so as to create an isolation region within the channel region.
